(19) United States
(12) Patent Application Publication
(10) Pub. No.: US 2026/0202487 A1
(43) Pub. Date: Jul. 16, 2026

(54) METHOD AND SYSTEM FOR ESTIMATING STATE OF HEALTH (SOH) OF A BATTERY

(71) Applicants: Dagnachew Birru, Marlborough, MA (US); Janak Maheshbhai Patel, Mumbai (IN); Milad Ramezankhani, Toronto (CA); Anirudh Deodhar, Mumbai (IN)

(72) Inventors: Dagnachew Birru, Marlborough, MA (US); Janak Maheshbhai Patel, Mumbai (IN); Milad Ramezankhani, Toronto (CA); Anirudh Deodhar, Mumbai (IN)

(73) Assignee: Quantiphi, Inc, Marlborough, MA (US)

(21) Appl. No.: 19/312,629

(22) Filed: Aug. 28, 2025

(51) Int. Cl. G01R 31/392; G01R 31/367

(52) U.S. Cl. CPC G01R 31/392; G01R 31/367

(57) ABSTRACT

A method (700) and system (100) for estimating State of Health (SOH) of battery (112) is disclosed. The method (700) includes receiving one or more parameters and time series operational data related to the battery(112). The method (700) includes estimating time series internal temperature profile of the battery (112) using neural network model based on the one or more parameters and the time series operational data. The neural network model is physics-informed Thermal Neural Module (TNM). The method (700) may further include generating synchronized multi-feature time series dataset based on time series operational data and the internal temperature profile. The method (700) includes estimating the SOH of the battery (112) based on generated synchronized multi-feature time series dataset using transformer-based model. The transformer-based model is Time-Informed Dynamic Sequence Inverted Transformer (TIDSIT). Further, the method (700) includes generating usage recommendations and maintenance actions based on the estimated SOH.

### FIELD OF THE INVENTION

The present disclosure relates to battery systems, transportation, and renewable energy, and more specifically to a method and system for estimating State of Health (SOH) of a battery.

### BACKGROUND OF THE INVENTION

With the global shift toward electrification and clean energy technologies, battery-powered systems such as Electric Vehicles (EVs) and Energy Storage Systems (ESSs) have gained substantial traction. The battery powered systems include a rechargeable lithium-ion batteries, known for high energy density and efficiency. The performance, reliability, and safety of such systems are heavily dependent on the State of Health (SOH) of the battery. The SOH is an essential metric indicating the remaining usable capacity relative to the battery's original rated capacity. Accurate SOH estimation is therefore critical for Battery Management Systems (BMS) to ensure optimal operation, safety, and lifecycle cost-efficiency.

Over time, batteries degrade due to complex electrochemical processes triggered by repeated charge-discharge cycles, varying thermal conditions, and irregular usage patterns. The degradation is often nonlinear and unpredictable, making it difficult to assess SOH with high accuracy. The challenge is exacerbated in real-world operational settings, where battery data is irregularly sampled, variable in length, multivariate and lacks internal temperature measurements, which are critical for understanding degradation behaviour.

Moreover, conventional approaches to battery SOH estimation can be broadly categorized into empirical models, which use predefined mathematical relationships to fit degradation curves, Physics-based models, which simulate internal electrochemical behaviour, and Data-driven machine learning models, such as Long Short-Term Memory (LSTM) networks, Convolutional Neural Networks (CNNs), and Support Vector Regression (SVR). However, most data-driven models rely on pre-processed data, such as interpolated sequences or handcrafted statistical features extracted from discharge cycles. The preprocessing step introduces temporal distortion, discards fine-grained sensor data, and limits the model's ability to learn nuanced degradation behaviour. Further, existing deep learning models often require fixed-length inputs, making them incompatible with the asynchronous and variable-length nature of real-world battery discharge data. As a result, the conventional approaches fail to deliver the robustness, generalizability, and accuracy required for practical deployment in safety-critical applications such as EVs and ESSs.

There is therefore a pressing need for a method and a system that estimate SOH of the battery with irregularly sampled, variable in length, multivariate operational data related to the battery.

### SUMMARY

The following embodiments presents a simplified summary in order to provide a basic understanding of some aspects of the disclosed invention. This summary is not an extensive overview, and it is not intended to identify key/critical elements or to delineate the scope thereof. Its sole purpose is to present some concepts in a simplified form as a prelude to the more detailed description that is presented later.

Some example embodiments disclosed herein provide a method estimating State of Health (SOH) of a battery, the method may include receiving one or more parameters and time series operational data related to the battery. The method may further include estimating a time series internal temperature profile of the battery using a neural network model based on the one or more parameters and the time series operational data. The neural network model is a physics-informed Thermal Neural Module (TNM). The method may further include generating a synchronized multi-feature time series dataset based on the time series operational data and the internal temperature profile. The method may further include estimating the SOH of the battery based on the generated synchronized multi-feature time series dataset using a transformer-based model. The transformer-based model is a Time-Informed Dynamic Sequence Inverted Transformer (TIDSIT). Further, the method includes generating usage recommendations and maintenance actions based on the estimated SOH.

According to some example embodiments, wherein the time series operational data related to the battery is irregularly sampled with variable sequence lengths.

According to some example embodiments, wherein the one or more parameters comprises physical parameters, thermal design parameters, and time series operational data comprising voltage, current, battery discharge cycles, and external temperature of the battery.

According to some example embodiments, wherein generating the synchronized multi-feature time series dataset comprises preprocessing the time series operational data to handle irregular sampling intervals and variable sequence lengths.

According to some example embodiments, wherein the method further includes applying continuous-time positional embeddings to represent irregular sampling intervals of the time series operational data as a continuous function of time.

According to some example embodiments, wherein the method further includes padding the time series operational data to handle variable length sequences. The method includes applying a temporal attention with masking mechanism to ignore the padded values of the time series operational data.

According to some example embodiments, wherein the method further includes applying inverting embeddings to time series operational data to capture inter-variable correlations across the entire variable sequence.

Some example embodiments disclosed herein provide a system for estimating State of Health (SOH) of a battery. The computer-implemented system includes a processor, and a memory communicatively coupled to the processor. The memory stores processor-executable instructions, which, on execution, cause the processor to receive one or more parameters and time series operational data related to the battery. The processor further estimate a time series internal temperature profile of the battery using a neural network model based on the one or more parameters and the time series operational data. The neural network model is a physics-informed Thermal Neural Module (TNM). The processor further generate a synchronized multi-feature time series dataset based on the time series operational data and the internal temperature profile. The processor further estimate the SOH of the battery based on the generated synchronized multi-feature time series dataset using a transformer-based model. The transformer-based model is a Time-Informed Dynamic Sequence Inverted Transformer (TIDSIT). Further, the processor may generate usage recommendations and maintenance actions based on the estimated SOH.

Some example embodiments disclosed herein provide a non-transitory computer-readable storage medium comprising instructions configured to estimate State of Health (SOH) of a battery, when executed, cause one or more processors to receive one or more parameters and time series operational data related to the battery. The processor further estimate a time series internal temperature profile of the battery using a neural network model based on the one or more parameters and the time series operational data. The neural network model is a physics-informed Thermal Neural Module (TNM). The processor further generate a synchronized multi-feature time series dataset based on the time series operational data and the internal temperature profile. The processor further estimate the SOH of the battery based on the generated synchronized multi-feature time series dataset using a transformer-based model. The transformer-based model is a Time-Informed Dynamic Sequence Inverted Transformer (TIDSIT). Further, the processor may generate usage recommendations and maintenance actions based on the estimated SOH.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

The above and still further example embodiments of the present invention will become apparent upon consideration of the following detailed description of embodiments thereof, especially when taken in conjunction with the accompanying drawings, and wherein:

FIG. 1 is a block diagram of an environment of a system for estimating State of Health (SOH) of a battery, in accordance with an example embodiment.

FIG. 2 is a block diagram illustrating various modules within a memory of a computing device configured for estimating SOH of the battery, in accordance with an example embodiment.

FIG. 3 illustrates a flow diagram of a method architecture for estimating SOH of the battery, in accordance with an example embodiment.

FIG. 4 illustrate a flow diagram of a method for estimating SOH of the battery, in accordance with an example embodiment.

FIG. 5 illustrate a flow diagram of a method for estimating time series internal temperature profile of the battery, in accordance with an example embodiment.

FIG. 6 illustrate a flow diagram of a method for estimating SOH of the battery, in accordance with an example embodiment.

FIG. 7 illustrate a flow diagram of a method for estimating SOH of the battery, in accordance with an example embodiment.

FIG. 8 is a block diagram of an exemplary computer system for implementing embodiments consistent with the present disclosure.

The figures illustrate embodiments of the invention for purposes of illustration only. One skilled in the art will readily recognize from the following description that alternative embodiments of the structures and methods illustrated herein may be employed without departing from the principles of the invention described herein.

### DETAILED DESCRIPTION

In the following description, for purposes of explanation, numerous specific details are set forth in order to provide a thorough understanding of the present invention. It will be apparent, however, to one skilled in the art that the present invention can be practiced without these specific details. In other instances, systems, apparatuses, and methods are shown in block diagram form only in order to avoid obscuring the present invention.

Reference in this specification to “one embodiment” or “an embodiment” or “example embodiment” means that a particular feature, structure, or characteristic described in connection with the embodiment is included in at least one embodiment of the present invention. The appearance of the phrase “in one embodiment” in various places in the specification are not necessarily all referring to the same embodiment, nor are separate or alternative embodiments mutually exclusive of other embodiments. Further, the terms “a” and “an” herein do not denote a limitation of quantity but rather denote the presence of at least one of the referenced items. Moreover, various features are described which may be exhibited by some embodiments and not by others. Similarly, various requirements are described which may be requirements for some embodiments but not for other embodiments.

Some embodiments of the present disclosure will now be described more fully hereinafter with reference to the accompanying drawings, in which some, but not all, embodiments of the invention are shown. Indeed, various embodiments of the invention may be embodied in many different forms and should not be construed as limited to the embodiments set forth herein; rather, these embodiments are provided so that this disclosure will satisfy applicable legal requirements. Like reference numerals refer to like elements throughout.

The terms “comprise”, “comprising”, “includes”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a system or apparatus proceeded by “comprises . . . a” does not, without more constraints, preclude the existence of other elements or additional elements in the system or method.

Furthermore, one or more computer-readable storage media may be utilized in implementing embodiments consistent with the present invention. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., are non-transitory. Examples include random access memory (RAM), read-only memory (ROM), volatile memory, non-volatile memory, hard drives, CD ROMs, DVDs, flash drives, disks, and any other known physical storage media.

The embodiments are described herein for illustrative purposes and are subject to many variations. It is understood that various omissions and substitutions of equivalents are contemplated as circumstances may suggest or render expedient but are intended to cover the application or implementation without departing from the spirit or the scope of the present invention. Further, it is to be understood that the phraseology and terminology employed herein are for the purpose of the description and should not be regarded as limiting. Any heading utilized within this description is for convenience only and has no legal or limiting effect.

### Definitions

The term “Battery” may refer to a rechargeable electrochemical energy storage device, such as a lithium-ion battery, configured to store and deliver electrical energy through charge and discharge cycles. The battery may be part of a battery-powered system including, but not limited to, electric vehicles (EVs) or energy storage systems (ESSs).

The term “State of Health (SOH) of the battery” may refer to a quantitative measure indicating the current condition or remaining usable capacity of the battery relative to its original (nominal) capacity. The SOH is typically expressed as a percentage and may be computed as the ratio of the current discharge capacity to the rated capacity of the battery.

The term “Irregular Data Sampling” may be used to refer to a data acquisition pattern in which sensor measurements such as voltage, current, and temperature are recorded at non-uniform time intervals rather than at fixed or regular sampling rates.

The term “Variable-Length Sequences” may refer to a series of data points such as sensor readings from battery discharge cycles whose total number of observations varies across different instances or cycles. In battery systems, each discharge cycle may contain a different number of measurements due to diverse usage patterns, sampling rates, battery aging, or interruptions in data collection.

The term “Thermal Neural Module (TNM)” may refer to a neural network-based computational model configured to estimate the internal temperature distribution of a battery based on available external sensor data (e.g., voltage, current, ambient temperature) and known thermal or physical parameters of the battery system.

The term “Time-Informed Dynamic Sequence Inverted Transformer (TIDSIT)” may refer to a specialized transformer-based deep learning architecture designed to estimate the SOH of the battery from raw, multivariate discharge cycle data that is irregularly sampled and variable in length. The TIDSIT model incorporates multiple key components, including continuous-time embeddings to capture non-uniform temporal intervals, data variate embeddings to model sensor-specific features (such as voltage, current, and temperature), and a temporal attention mechanism to process padded sequences without losing temporal fidelity.

The term “Continuous-time positional embedding” may refer to a learned representation technique used to encode the precise timing of sensor measurements that occur at irregular intervals within a time series. The continuous-time positional embeddings model time as a continuous variable, allowing the system to capture temporal dependencies and order information in sequences with non-uniform time gaps.

The term “Inverted Embedding Mechanism” may refer to a neural encoding technique wherein multivariate time-series data is transposed such that the embedding is performed across feature dimensions (e.g., voltage, current, temperature) instead of time steps. The inversion allows the attention mechanism in transformer architectures to model cross-feature dependencies more effectively, rather than focusing solely on temporal relationships.

The term “Temporal Attention with Padded Sequences” may refer to a mechanism within a transformer-based model that enables the processing of variable-length time-series data by applying attention selectively over valid (non-padded) time steps. The temporal attention mechanism incorporates padding masks to ignore artificially added values during training and inference, while still capturing temporal dependencies across the actual data points.

The term “module” used herein may refer to a hardware processor including a Central Processing Unit (CPU), an Application-Specific Integrated Circuit (ASIC), an Application-Specific Instruction-Set Processor (ASIP), a Graphics Processing Unit (GPU), a Physics Processing Unit (PPU), a Digital Signal Processor (DSP), a Field Programmable Gate Array (FPGA), a Programmable Logic Device (PLD), a Controller, a Microcontroller unit, a Processor, a Microprocessor, an ARM, or the like, or any combination thereof.

### End of Definitions

Accurate estimation of the State of Health (SOH) of batteries is essential for ensuring the safety, reliability, and performance of battery-powered systems such as electric vehicles (EVs) and energy storage systems (ESSs). However, conventional data-driven approaches suffer from significant limitations when applied to real-world battery data. The real-world battery data may be irregularly sampled meaning measurements are recorded at non-uniform time intervals, variable in sequence length due to differences in usage patterns and sensor logging, lack internal temperature data which is critical for understanding degradation and dependent on handcrafted feature extraction which may result in information loss. Conventional machine learning and transformer models are ill-equipped to handle these challenges directly, requiring pre-processing or windowing that compromises temporal integrity and reduces prediction accuracy. As a result, conventional solutions often fail to provide robust and scalable SOH estimation in practical deployment scenarios.

The present disclosure addresses these challenges by introducing a Physics-Augmented Data-Driven Neural Twin system for battery SOH estimation. The Physics-Augmented Data-Driven Neural Twin system may combine a Thermal Neural Module (TNM) and a Time-Informed Dynamic Sequence Inverted Transformer (TIDSIT). The TNM is designed to estimate the internal temperature profile of the battery using external operating parameters and physical characteristics, enabling the inclusion of thermal dynamics in SOH estimation without the need for invasive internal sensors. Further, the TIDSIT may directly processes irregular, variable-length multivariate discharge sequences using continuous-time positional embeddings to preserve non-uniform time intervals, inverted embedding mechanisms to capture cross-feature interactions, and temporal attention with padding masks to handle variable-length inputs without truncation or interpolation. The present disclosure enable accurate, end-to-end estimation of battery SOH from raw, real-world sensor data, eliminating the need for handcrafted features or rigid sampling constraints, and outperforming conventional solutions in both accuracy and generalizability.

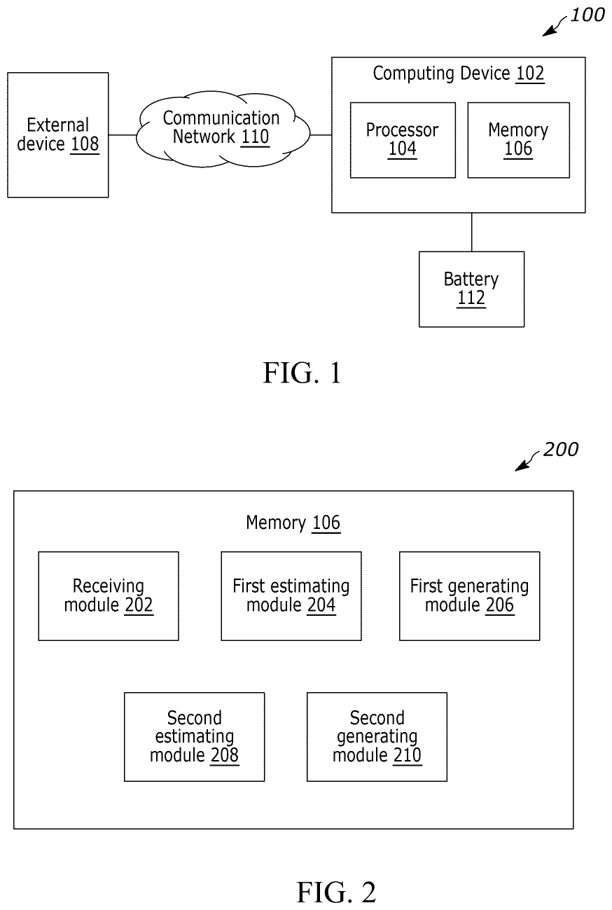

Embodiments of the present disclosure may provide a method, a system, and a computer program product for estimating SOH of the battery. The method, the system, and the computer program product estimates the SOH of the battery in such an improved manner are described with reference to FIG. 1 to FIG. 8 as detailed below.

FIG. 1 illustrates a block diagram of an environment of a system 100 for estimating State of Health (SOH) of a battery 112, in accordance with an example embodiment. The system 100 is designed to facilitate efficient and accurate estimation of the SOH of the battery 112. The system 100 includes a computing device 102, an external device 108 and the battery 112. The computing device 102 may be communicatively coupled with the external device 108 via a communication network 110. Examples of the computing device 102 may include, but are not limited to, a server, a desktop, a laptop, a notebook, a tablet, a smartphone, a mobile phone, an application server, or the like.

The communication network 110 may be wired, wireless, or any combination of wired and wireless communication networks, such as cellular, Wi-Fi, internet, local area networks, or the like. In one embodiment, the communication network 110 may include one or more networks such as a data network, a wireless network, a telephony network, or any combination thereof. It is contemplated that the data network may be any local area network (LAN), metropolitan area network (MAN), wide area network (WAN), a public data network (e.g., the Internet), short range wireless network, or any other suitable packet-switched network, such as a commercially owned, proprietary packet-switched network, e.g., a proprietary cable or fiber-optic network, and the like, or any combination thereof. In addition, the wireless network may be, for example, a cellular network and may employ various technologies including enhanced data rates for global evolution (EDGE), general packet radio service (GPRS), global system for mobile communications (GSM), Internet protocol multimedia subsystem (IMS), universal mobile telecommunications system (UMTS), etc., as well as any other suitable wireless medium, e.g., worldwide interoperability for microwave access (WiMAX), Long Term Evolution (LTE) networks, code division multiple access (CDMA), wideband code division multiple access (WCDMA), wireless fidelity (Wi-Fi), wireless LAN (WLAN), Bluetooth®, Internet Protocol (IP) data casting, satellite, mobile ad-hoc network (MANET), and the like, or any combination thereof.

The computing device 102 may include a memory 106, and a processor 104. The term “memory” used herein may refer to any computer-readable storage medium, for example, volatile memory, random access memory (RAM), non-volatile memory, read only memory (ROM), or flash memory. The memory 106 may include a Random-Access Memory (RAM), a Read-Only Memory (ROM), a Complementary Metal Oxide Semiconductor Memory (CMOS), a magnetic surface memory, a Hard Disk Drive (HDD), a floppy disk, a magnetic tape, a disc (CD-ROM, DVD-ROM, etc.), a USB Flash Drive (UFD), or the like, or any combination thereof.

The term “processor” used herein may refer to a hardware processor including a Central Processing Unit (CPU), an Application-Specific Integrated Circuit (ASIC), an Application-Specific Instruction-Set Processor (ASIP), a Graphics Processing Unit (GPU), a Physics Processing Unit (PPU), a Digital Signal Processor (DSP), a Field Programmable Gate Array (FPGA), a Programmable Logic Device (PLD), a Controller, a Microcontroller unit, a Processor, a Microprocessor, an ARM, or the like, or any combination thereof.

The processor 104 may retrieve computer program code instructions that may be stored in the memory 106 for execution of the computer program code instructions. The processor 104 may be embodied in a number of different ways. For example, the processor 104 may be embodied as one or more of various hardware processing means such as a coprocessor, a microprocessor, a controller, a digital signal processor (DSP), a processing element with or without an accompanying DSP, or various other processing circuitry including integrated circuits such as, for example, an ASIC (application specific integrated circuit), an FPGA (field programmable gate array), a microcontroller unit (MCU), a hardware accelerator, a special-purpose computer chip, or the like. As such, in some embodiments, the processor 104 may include one or more processing cores configured to perform independently. A multi-core processor may enable multiprocessing within a single physical package. Additionally, or alternatively, the processor 104 may include one or more processors configured in tandem via the bus to enable independent execution of instructions, pipelining, and/or multithreading.

Additionally, or alternatively, the processor 104 may include one or more processors capable of processing large volumes of workloads and operations to provide support for big data analysis. In an example embodiment, the processor 104 may be in communication with a memory 106 via a bus for passing information among components of the system 100.

The memory 106 may be non-transitory and may include, for example, one or more volatile and/or non-volatile memories. In other words, for example, the memory 106 may be an electronic storage device (for example, a computer readable storage medium) comprising gates configured to store data (for example, bits) that may be retrievable by a machine (for example, a computing device like the processor 104). The memory 106 may be configured to store information, data, contents, applications, instructions, or the like, for enabling the apparatus to carry out various functions in accordance with an example embodiment of the present disclosure. For example, the memory 106 may be configured to buffer input data for processing by the processor 104.

The battery 112 may be a rechargeable electrochemical energy storage device such as a lithium-ion battery that serves as a critical component in systems such as Electric Vehicles (EVs) and Energy Storage Systems (ESSs). The battery 112 undergoes repetitive charge and discharge cycles, during which its performance degrades over time due to electrochemical and thermal stress. The degradation affects State of Health (SOH) of the battery 112, a key metric that reflects the battery's current capacity relative to its nominal capacity. The battery 112 is characterized by multivariate operational data, including voltage, current, and temperature measurements, often recorded at irregular time intervals and over variable-length discharge sequences.

The computing device 102 may be capable of estimating State of Health (SOH) of the battery 112. The memory 106 may store instructions that, when executed by the processor 104, cause the computing device 102 to perform one or more operations of the present disclosure which will be described in greater detail in conjunction with FIG. 2. The computing device 102 is responsible for receiving one or more parameters and time series operational data related to the battery. The computing device 102 is further responsible for estimating a time series internal temperature profile of the battery 112 using a neural network model based on the one or more parameters and the time series operational data. The neural network model is a physics-informed Thermal Neural Module (TNM). Further, the computing device 102 is responsible for generating a synchronized multi-feature time series dataset based on the time series operational data and the internal temperature profile. The computing device 102 is responsible for estimating the SOH of the battery 112 based on the generated synchronized multi-feature time series dataset using a transformer-based model. The transformer-based model is a Time-Informed Dynamic Sequence Inverted Transformer (TIDSIT). Further, the computing device 102 is responsible for generating usage recommendations and maintenance actions based on the estimated SOH.

The external device 108 may refers to various hardware and software tools that may be integrated with the system 100 to enhance its functionality. These devices may include database. The database is essential for generating ontology and mapping files according to business use case. The complete process followed by the system 100 is explained in detail in conjunction with FIG. 2 to FIG. 8.

FIG. 2 illustrates a block diagram 200 illustrating various modules within the memory 106 of the computing device 102 configured for estimating SOH of the battery 112, in accordance with an example embodiment. The memory 106 may include a receiving module 202, a first estimating module 204, a first generating model 206, a second estimating module 208, and a second generating module 210.

The receiving module 202 may be configured to receive one or more parameters and time series operational data related to the battery. The time series operational data related to the battery 112 is irregularly sampled with variable sequence lengths. Further, the one or more parameters may include physical parameters, thermal design parameters, and time series operational data may include voltage recorded over discharge cycles, current measurements captured during charge and discharge events, battery discharge cycles which may vary in duration and sampling frequency, and external temperature of the battery 112. The time series operational data may be obtained from onboard sensors, external diagnostic systems, or data loggers connected to the battery system in real-time or from historical logs. Further, the physical parameters may include cell configuration, internal resistance, rated capacity, nominal voltage, and battery chemistry. The thermal design parameters may include thermal conductivity, heat capacity, cooling path configuration, and external environmental constraints.

The first estimating module 204 may be configured to estimate a time series internal temperature profile of the battery 112 using a neural network model based on the one or more parameters and the time series operational data. The neural network model is a physics-informed Thermal Neural Module (TNM). The TNM is a physics-informed model that leverages both data-driven learning and thermal physics principles to infer internal battery temperatures critical for accurate estimation of State of Health (SOH) of the battery 112. The internal temperature profile may be the estimated temperature values inside the battery 112 (e.g., core temperature or distributed thermal map) over a given time period or during a discharge cycle. The internal temperatures may not be measured directly in most real-world systems due to sensor placement limitations or cost and safety constraints, but they have a significant influence on degradation mechanisms such as SEI growth, lithium plating, and thermal runaway risks.

To estimate the internal temperature profile, the TNM may receive the one or more parameters and time series operational data related to the battery 112 from the receiving module 202. The temporal information such as time steps between samples is preserved to account for the irregular sampling pattern. Further, the first estimating module 204 may encode some features through neural layers of the TNM that incorporate domain-specific constraints, for example, enforcing energy conservation and heat transfer principles via custom layers or loss functions. Further, the TNM may simulate heat generation and dissipation inside the battery 112. In an embodiment, Heat generation may be modelled as a function of Joule heating (I²R losses) and entropic heating, derived from input current and battery resistance. Further, Heat dissipation may be modelled based on external temperature and the battery's thermal properties. In an embodiment, the TNM employs a recurrent or convolutional neural network architecture to estimate the internal temperature trajectory over time. The TNM learns patterns from physics and historical data if ground-truth internal temperatures are known such as from lab testing and it generalizes the patterns to new sequences using received data alone. The TNM outputs a time-series temperature profile such as a sequence of estimated internal temperature values for each timestamp in the discharge cycle. The temperature profile captures dynamic changes in internal battery 112 conditions as a function of load, ambient temperature, and thermal inertia. By incorporating physics-informed constraints into the learning process, the TNM ensures that the estimated temperature values are thermodynamically realistic and consistent with the battery's physical behaviour. The estimated temperature profile is then used as a critical input to the second estimating module 208 to enhance the accuracy and robustness of the SOH estimation.

The first generating module 206 may be configured to generate a synchronized multi-feature time series dataset based on the time series operational data and the internal temperature profile. The first generating module 206 may preprocess the time series operational data to handle irregular sampling intervals and variable sequence lengths. In an embodiment, the operational data such as voltage, current, and external temperature and the internally estimated internal temperature profile values are initially recorded or estimated at non-uniform time intervals and may vary in length across discharge cycles due to real-world sampling constraints. To prepare the received data for estimating SOH of the battery 112, the first generating module 206 may aligns operational data, and internal temperature profile along a common time reference. When exact timestamp overlap does not exist such as current is sampled at different times than temperature, the first generating module 206 may use interpolation or forward-filling techniques within defined error tolerances to ensure that all feature values are synchronized to the same set of time points. Further, the first generating module 206 constructs a feature vector at each time point comprising the synchronized values of operational data, and internal temperature profile, resulting in a multivariate time-series sequence, where each entry corresponds to a complete feature set for a single timestamp.

The second estimating module 208 may be configured to estimate the SOH of the battery 112 based on the generated synchronized multi-feature time series dataset using a transformer-based model. The transformer-based model is a Time-Informed Dynamic Sequence Inverted Transformer (TIDSIT). The second estimating module 208 may apply continuous-time positional embeddings to represent irregular sampling intervals of the time series operational data as a continuous function of time. Further, the second estimating module 208 may apply padding of the time series operational data to handle variable length sequences. The second estimating module 208 may apply a temporal attention with masking mechanism to ignore the padded values of the time series operational data. Further, the second estimating module 208 may apply inverting embeddings to time series operational data to capture inter-variable correlations across the entire variable sequence. To enable batch processing of data sequences with differing lengths such as different numbers of time steps across discharge cycles, the second estimating module 208 applies padding to the input sequences. Shorter sequences are extended to the length of the longest sequence within the batch using placeholder values such as zero or NaN. Padding ensure compatibility with the TIDSIT attention mechanism, which requires uniform input shapes across batch entries.

Further, to ensure that padded values do not affect the TIDSIT attention computations, the second estimating module 208 may apply a temporal attention with masking mechanism. The mask identifies valid time steps and ignores padded entries during attention score calculation and gradient updates. In some embodiments, the second estimating module 208 may apply an inverted embedding mechanism to better TIDSIT inter-variable correlations within the time-series data. The inverted embedding transposes the input tensor to emphasize the feature dimension such as voltage, current, external, and internal temperatures, enabling the TIDSIT to capture cross-feature dependencies, such as how current changes in response to voltage or how internal temperature correlates with discharge behaviour. Further, a history of SOH history of the battery 112 are embedded into the TIDSIT to incorporate contextual trends from prior discharge cycles. The continuous time embeddings, the inverting embeddings, and padding passed through a transformer encoder, which models both intra-cycle sensor dynamics and inter-cycle degradation trends to generate accurate SOH estimates across diverse batteries and usage profiles.

The second generating module 210 may be configured to generate usage recommendations and maintenance actions based on the estimated SOH. The second generating module 210 receives the numerical SOH value such as a floating-point value between 0 and 1 or a percentage and maps it to predefined operational categories based on configurable thresholds, for example, healthy (SOH>=90%), moderately degraded (70%≤SOH<90%), severely degraded (50%≤SOH<70%), and critical (SOH<50%). Based on the interpreted SOH category and historical or contextual usage data, the second generating module 210 may generate real-time or scheduled usage recommendations. The usage recommendations may include adaptive charging strategies such as avoid fast charging at low temperatures, load moderation instructions such as reduce power draw during peak operation periods, environmental advisories such as avoid high ambient temperature conditions, and operational scheduling such as defer energy-intensive tasks until battery temperature stabilizes. The usage recommendations may be delivered to users or autonomous control systems such as a vehicle's ECU or an ESS controller to optimize battery 112 utilization. Further, the maintenance actions may include alerts for battery replacement or inspection, recalibration routines within the Battery Management System (BMS), firmware updates to adjust thermal or charging behaviour, and scheduling maintenance windows or disabling high-load modes.

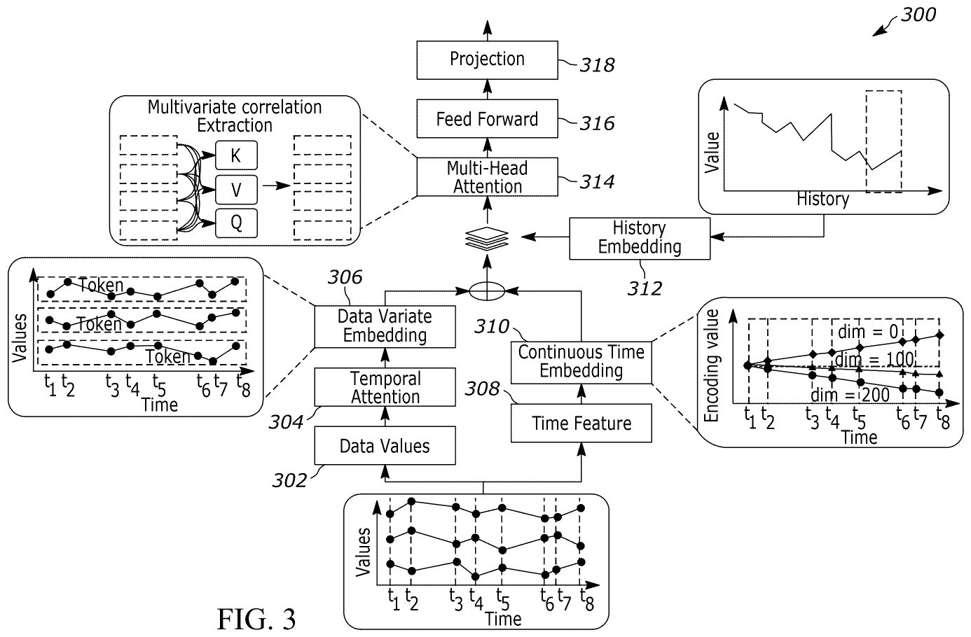

FIG. 3 illustrates a flow diagram of a method 300 for estimating SOH of the battery 112, in accordance with an example embodiment. The method 300 may be implemented by the Time-Informed Dynamic Sequence Inverted Transformer (TIDSIT).

At step 302, the TIDSIT may receive multivariate sensor data collected over a discharge cycle. The multi-variate sensor data may include voltage, current, external temperature and estimated internal temperature received from the TNM as explained in detail in FIG. 2. The data may be irregularly sampled over time, with each feature having multiple measurement points across a discharge cycle.

At step 304, the multivariate sensor data passed through a temporal attention module configured to apply masking to ignore padded or artificial values (added during sequence padding). The temporal attention module may enable learning of temporal dependencies even in irregular and variable-length sequences, resulting a temporally attended representation of the original discharge sequence.

At step 306, the output from temporal attention is then passed to a data variate embedding module. The data variate embedding module may transpose the data representation to treat each sensor data such as voltage, current, temperature as a distinct channel. The data variate embedding module may embed each channel independently to model inter-variable correlations and produce a latent feature representation for each sensor type across time. The inverted embedding allows attention layers to learn cross-feature interactions, which is critical for multivariate time-series modelling.

At step 308, the TIDSIT may receive time feature vector extracted from the input data and processed into a normalized time feature representation.

At step 310, the time feature representation is input into a continuous time embedding module. The continuous time embedding module may encode non-uniform temporal intervals between measurements. Further, the continuous time embedding module may project timestamps into a continuous latent space using learnable parameters, preserving the true timing of events, which is often distorted in conventional sequence models.

In an embodiment, the TIDSIT may add the data variate embedding and the continuous-time embedding via element-wise summation to form a unified embedding that enables the model to encode both the semantic structure of individual features and the underlying temporal dynamics within a unified representation.

At step 312, the TIDSIT may receive a SOH history embedding from previously estimated SOH values from earlier discharge cycles. The TIDSIT may embed past SOH predictions into a fixed-size vector, adding inter-cycle degradation trends into the current prediction context. The SOH history embedding may enable the TIDSIT to leverage historical degradation context.

At step 314, the unified embedding is further concatenated with the history embedding and passed into a multi-head attention block. The multi-head attention block may apply self-attention to TIDSIT dependencies across time steps and features, enabling the TIDSIT to learn complex intra-cycle relationships, such as voltage-current-temperature interactions at different times.

At step 316, the attended representation is then passed through a position-wise feed forward neural network, which apply nonlinear transformations to extract high-level representations, distilling task-specific features for SOH estimation.

At step 318, the transformed feature vector is passed through a projection layer, which outputs a scalar value representing the estimated SOH of the battery 112 at the current cycle. The estimated SOH value reflects the battery's current capacity as a fraction or percentage of its rated capacity.

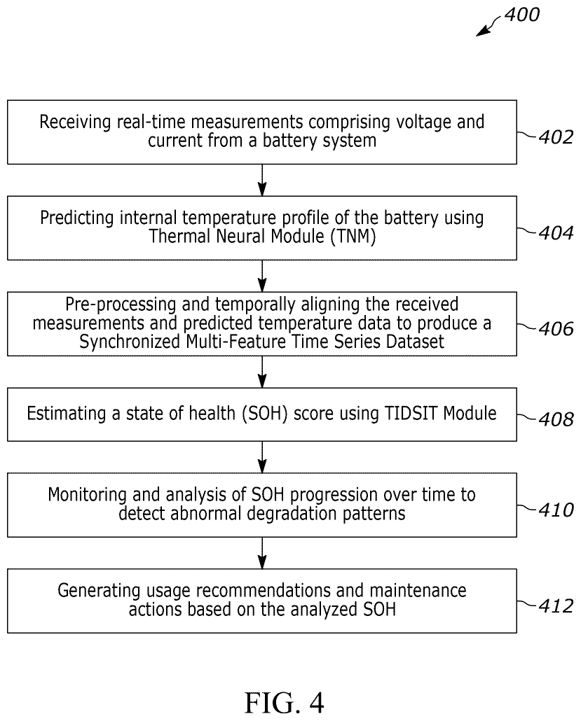

FIG. 4 illustrates a flow diagram of a method 400 for estimating SOH of the battery 112, in accordance with an example embodiment. FIG. 4 is explained in conjunction with elements from FIGS. 1, 2, and 3. It will be understood that each block of the flow diagram of the method 400 may be implemented by various means, such as hardware, firmware, processor, circuitry, and/or other communication devices associated with execution of software including one or more computer program instructions. For example, one or more of the procedures described above may be embodied by computer program instructions. In this regard, the computer program instructions which embody the procedures described above may be stored by a memory 106 of the computing device 102, employing an embodiment of the present disclosure and executed by a processor 104. As will be appreciated, any such computer program instructions may be loaded onto a computer or other programmable apparatus (for example, hardware) to produce a machine, such that the resulting computer or other programmable apparatus implements the functions specified in the flow diagram blocks. These computer program instructions may also be stored in a computer-readable memory that may direct a computer or other programmable apparatus to function in a particular manner, such that the instructions stored in the computer-readable memory produce an article of manufacture the execution of which implements the function specified in the flowchart blocks. The computer program instructions may also be loaded onto a computer or other programmable apparatus to cause a series of operations to be performed on the computer or other programmable apparatus to produce a computer-implemented process such that the instructions which execute on the computer or other programmable apparatus provide operations for implementing the functions specified in the flow diagram blocks.

Accordingly, blocks of the flow diagram support combinations of means for performing the specified functions and combinations of operations for performing the specified functions for performing the specified functions. It will also be understood that one or more blocks of the flow diagram, and combinations of blocks in the flow diagram, may be implemented by special purpose hardware-based computer systems which perform the specified functions, or combinations of special purpose hardware and computer instructions.

At step 402, the TNM model may receive real-time measurements including voltage and current from a battery system. The real-time measurements may be raw, multivariate sensor data from the battery during a discharge cycle. The real-time measurements may include voltage, current measurement, external temperature readings. The real time measurements are collected at non-uniform time intervals, resulting in irregularly sampled time-series data.

At step 404, the TNM model may predict internal temperature profile of the battery. Due to the absence of internal temperature sensors in most commercial battery systems, the Thermal Neural Module (TNM) leverages a physics-informed neural network model to estimate the internal temperature dynamics of the battery. The TNM may receive operational parameters such as voltage, current, external temperatures, and physical and thermal characteristics. Further, the TNM may produce a time-series internal temperature profile, which is critical for accurate modelling of degradation behaviour and SOH estimation.

At step 406, a preprocessor model may pre-process and temporally align received operational data and predicted internal temperature profile to produce a synchronized multi-feature time series dataset. The TIDSIT may synchronize all time-series inputs such as voltage, current, external, and internal temperature profile onto a unified temporal grid. Further, the TIDSIT module may handle irregular sampling and sequence length variability via masking or interpolation, padding sequences to match batch processing requirements. In an embodiment, the TIDSIT model may provide a clean, multivariate, synchronized dataset, ready to be processed.

At step 408, the TIDSIT model may estimate the State of health (SOH) score. The TIDIST model incorporate continuous-time embeddings to handle irregular time steps and apply temporal attention and inverted embedding mechanisms to model both temporal and cross-feature relationships. Further, the TIDSIT process the variable length sequences end-to-end, without truncation or handcrafted feature extraction. Finally, the TIDSIT model outputs a scalar SOH value, representing the current health condition of the battery 112 relative to its original capacity.

At step 410, the SOH progression is monitored and analyzed over time to detect abnormal degradation patterns. Once SOH estimates are generated across multiple discharge cycles, the TIDSIT model may track the trend of the SOH overtime. The TIDSIT may identify abnormal drops or nonlinear degradation signatures that may indicate issues such as cell imbalance, thermal stress, and accelerated aging.

At step 412, the TIDSIT model may generate usage recommendations and maintenance actions based on the analysed SOH. Based on the estimated and analysed SOH, the TIDSIT model may generate context-aware recommendations such as charging or discharging guidance, load limiting instructions, and environmental usage constraints.

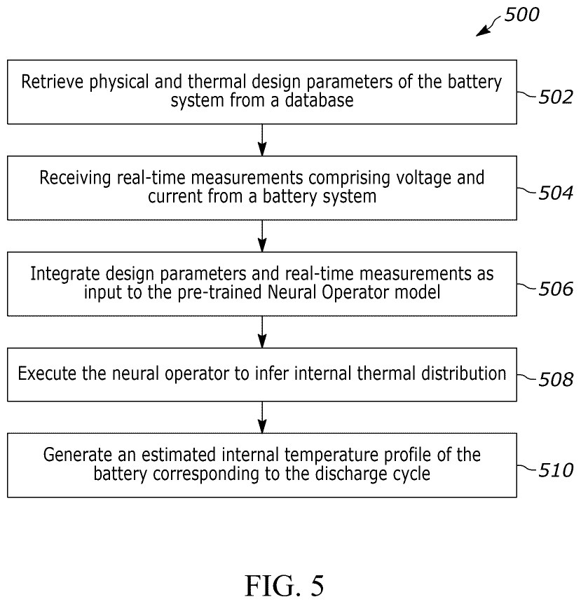

FIG. 5 illustrates a flow diagram of a method 500 for estimating time series internal temperature profile of the battery, in accordance with an example embodiment. FIG. 5 is explained in conjunction with elements from FIGS. 1, 2, 3, and 4. The method 500 may be implemented by the TNM. It will be understood that each block of the flow diagram of the method 500 may be implemented by various means, such as hardware, firmware, processor, circuitry, and/or other communication devices associated with execution of software including one or more computer program instructions. For example, one or more of the procedures described above may be embodied by computer program instructions. In this regard, the computer program instructions which embody the procedures described above may be stored by a memory 106 of the computing device 102, employing an embodiment of the present disclosure and executed by a processor 104. As will be appreciated, any such computer program instructions may be loaded onto a computer or other programmable apparatus (for example, hardware) to produce a machine, such that the resulting computer or other programmable apparatus implements the functions specified in the flow diagram blocks. These computer program instructions may also be stored in a computer-readable memory that may direct a computer or other programmable apparatus to function in a particular manner, such that the instructions stored in the computer-readable memory produce an article of manufacture the execution of which implements the function specified in the flowchart blocks. The computer program instructions may also be loaded onto a computer or other programmable apparatus to cause a series of operations to be performed on the computer or other programmable apparatus to produce a computer-implemented process such that the instructions which execute on the computer or other programmable apparatus provide operations for implementing the functions specified in the flow diagram blocks.

Accordingly, blocks of the flow diagram support combinations of means for performing the specified functions and combinations of operations for performing the specified functions for performing the specified functions. It will also be understood that one or more blocks of the flow diagram, and combinations of blocks in the flow diagram, may be implemented by special purpose hardware-based computer systems which perform the specified functions, or combinations of special purpose hardware and computer instructions.

At step 502, the TNM may retrieve physical and thermal design parameters of the battery system from a database. The parameters serve as critical contextual inputs that enable the TNM to model the internal thermal behaviour of the battery with greater accuracy. The physical and thermal parameters may include, but are not limited to, battery geometry and dimensions, battery configurations, material properties, internal resistance values, cooling system designs, sensor placement information, and manufacturing or chemistry-specific attributes.

At step 504, the TNM may retrieve real-time measurements comprising voltage and current from a battery system. The real-time measurements are essential for estimating the internal temperature profile of the battery 112, as they reflect the instantaneous electrical load and thermal stress experienced by the battery during operation. The real-time measurements are collected at irregular time intervals (e.g., t₁, t₂, . . . , tₙ), and over a discharge cycle, representing the operational behaviour of the battery under realistic usage conditions. The TNM may uses the voltage and current data to estimate the rate of heat generation within the battery 112.

At step 506, the TNM may integrate the physical and thermal design parameters and the real-time measurements as input to a pre-trained neural operator model. The pre-trained neural operator model is designed to estimate the internal temperature profile of a battery system with high fidelity by leveraging both physics-informed characteristics and data-driven learning. The pre-trained neural operator model is a physics-augmented deep learning network, designed to learn mappings from operating conditions to internal thermal states. Further, the neural operator models are capable of learning functional mappings over continuous domains, making them ideal for modelling partial differential equations (PDEs) or physical systems like heat transfer in batteries 112.

At step 508, the TNM may execute the neural operator to infer internal thermal distribution. The neural operator model apply learned spatial and temporal operators, such as kernel integral operators or attention-based mechanisms, to propagate energy through the modeled thermal system, producing a time-series profile of internal temperature values of the battery 112.

At step 510, the TNM may generate an estimated internal temperature profile of the battery 112 corresponding to the discharge cycle. The internal temperature profile may include a sequence of estimated internal temperature values aligned with the timestamps of the discharge cycle. The internal temperature profile may represent core temperature at each time step and multi-point spatial temperature distribution within the battery such as core, surface, edge regions. Each data point in the internal temperature profile corresponds to a predicted internal temperature at a specific moment during the discharge event, accounting for real-time current flow, voltage, and the thermal properties of the battery 112.

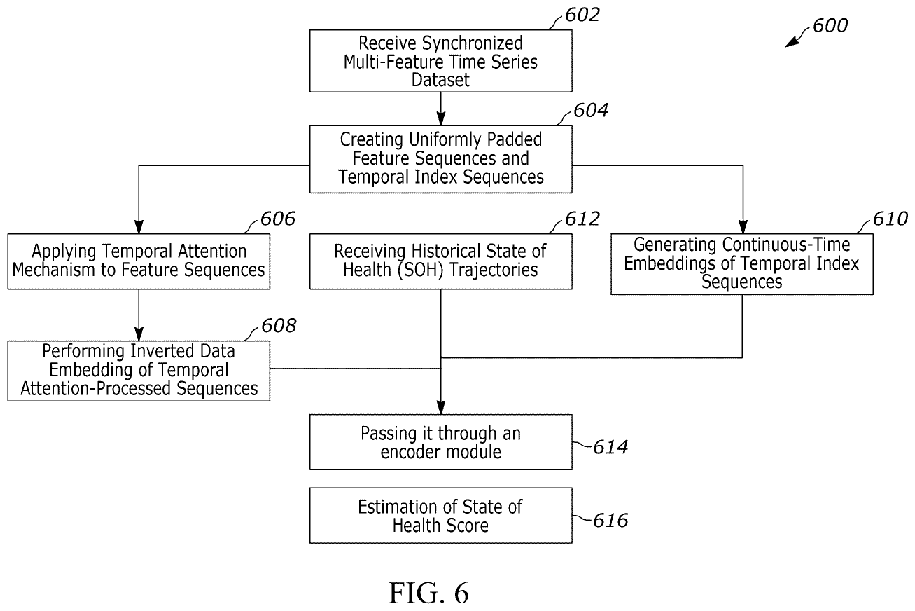

FIG. 6 illustrates a flow diagram of a method 600 for estimating SOH of the battery 112, in accordance with an example embodiment. FIG. 6 is explained in conjunction with elements from FIGS. 1, 2, 3, 4 and 5. The method 600 may be implemented by the TIDSIT model. It will be understood that each block of the flow diagram of the method 600 may be implemented by various means, such as hardware, firmware, processor, circuitry, and/or other communication devices associated with execution of software including one or more computer program instructions. For example, one or more of the procedures described above may be embodied by computer program instructions. In this regard, the computer program instructions which embody the procedures described above may be stored by a memory 106 of the computing device 102, employing an embodiment of the present disclosure and executed by a processor 104. As will be appreciated, any such computer program instructions may be loaded onto a computer or other programmable apparatus (for example, hardware) to produce a machine, such that the resulting computer or other programmable apparatus implements the functions specified in the flow diagram blocks. These computer program instructions may also be stored in a computer-readable memory that may direct a computer or other programmable apparatus to function in a particular manner, such that the instructions stored in the computer-readable memory produce an article of manufacture the execution of which implements the function specified in the flowchart blocks. The computer program instructions may also be loaded onto a computer or other programmable apparatus to cause a series of operations to be performed on the computer or other programmable apparatus to produce a computer-implemented process such that the instructions which execute on the computer or other programmable apparatus provide operations for implementing the functions specified in the flow diagram blocks.

Accordingly, blocks of the flow diagram support combinations of means for performing the specified functions and combinations of operations for performing the specified functions for performing the specified functions. It will also be understood that one or more blocks of the flow diagram, and combinations of blocks in the flow diagram, may be implemented by special purpose hardware-based computer systems which perform the specified functions, or combinations of special purpose hardware and computer instructions.

At step 602, the TIDSIT model may receive synchronized multi-feature time series dataset. The multi-feature time series dataset may include aligned measurements of voltage, current, external temperature, estimated internal temperature profile, and timestamps associated with each measurements. Each sequence corresponds to a complete battery discharge cycle, and the data is pre-processed to maintain temporal integrity across all features.

At step 604, the TIDSIT model may create uniformly padded feature sequences and temporal index sequences. The TIDSIT model may pad the shorter sequences with dummy or null values (e.g., NaN or zeros) to match the length of the longest sequence in a batch. Further, the TIDSIT model generates a temporal index sequence representing the time or position of each measurement (e.g., as relative timestamps or actual time deltas).

At step 606, the TIDSIT model may apply a temporal attention mechanisms to feature sequences. The TIDSIT model may use self-attention layers to model dependencies across different time steps, allowing the TIDSIT model to identify critical time intervals in the degradation sequence. Further, the TIDSIT model apply a temporal attention with masking mechanism to ensure that padded (non-real) values are excluded from the attention computation, preserving the fidelity of learned temporal patterns.

At step 608, the TIDSIT model may perform inverted data embeddings of temporal attention processed sequences. Further, the TIDSIT model may transpose the sequence tensor so that embeddings are applied across the feature dimension such as voltage, current, temperature, rather than across time. The TIDSIT model may embed each feature independently to capture cross-variable relationships and interactions such as how temperature changes affect current behaviour.

At step 610, the TIDSIT model may generate continuous time embeddings of temporal index sequences. The TIDSIT model may encode irregular time intervals between samples as learnable, continuous functions such as sinusoidal or neural positional embeddings. Further, the TIDSIT model may allow the transformer to retain true timing information that may otherwise be lost in padding or truncation.

At step 612, the TIDSIT model may receive historical SOH trajectories of the battery 112. The historical SOH values provide context that may improve the TIDSIT's ability to forecast the current or future SOH, when battery degradation is nonlinear or condition dependent.

At step 614, the TIDSIT model may pass the inverted data embeddings, continuous time embeddings, and the historical SOH trajectories through an encoder module. The TIDSIT model may fuse the inverted feature embeddings, the continuous-time embeddings, and the historical SOH embeddings. Further, the encoder module may apply multi-head attention to jointly process temporal and feature dependencies, layer normalization and residual connections to stabilize learning, and feed-forward networks to project features into a latent health representation.

At step 616, the TIDSIT model may estimate the SOH of the battery 112. The output of the encoder module is passed through a projection or regression head that outputs the estimated State of Health (SOH) for the current discharge cycle. The SOH may be expressed as a scalar value, such as a percentage, or a normalized value.

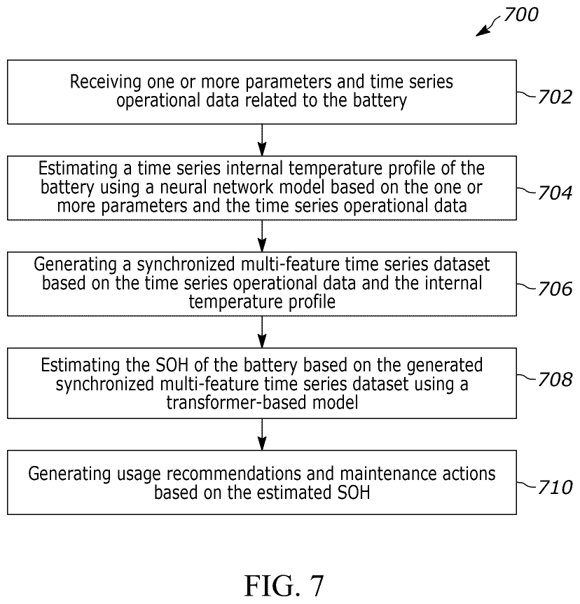

FIG. 7 illustrates a flow diagram of a method 700 for estimating SOH of the battery 112, in accordance with an example embodiment. FIG. 7 is explained in conjunction with elements from FIGS. 1, 2, 3, 4, 5 and 6. It will be understood that each block of the flow diagram of the method 700 may be implemented by various means, such as hardware, firmware, processor, circuitry, and/or other communication devices associated with execution of software including one or more computer program instructions. For example, one or more of the procedures described above may be embodied by computer program instructions. In this regard, the computer program instructions which embody the procedures described above may be stored by a memory 106 of the computing device 102, employing an embodiment of the present disclosure and executed by a processor 104. As will be appreciated, any such computer program instructions may be loaded onto a computer or other programmable apparatus (for example, hardware) to produce a machine, such that the resulting computer or other programmable apparatus implements the functions specified in the flow diagram blocks. These computer program instructions may also be stored in a computer-readable memory that may direct a computer or other programmable apparatus to function in a particular manner, such that the instructions stored in the computer-readable memory produce an article of manufacture the execution of which implements the function specified in the flowchart blocks. The computer program instructions may also be loaded onto a computer or other programmable apparatus to cause a series of operations to be performed on the computer or other programmable apparatus to produce a computer-implemented process such that the instructions which execute on the computer or other programmable apparatus provide operations for implementing the functions specified in the flow diagram blocks.

Accordingly, blocks of the flow diagram support combinations of means for performing the specified functions and combinations of operations for performing the specified functions for performing the specified functions. It will also be understood that one or more blocks of the flow diagram, and combinations of blocks in the flow diagram, may be implemented by special purpose hardware-based computer systems which perform the specified functions, or combinations of special purpose hardware and computer instructions.

At step 702, the method 700 may include receiving one or more parameters and time series operational data related to the battery 112. The time-series operational data may include voltage measurements, current values, ambient or external temperatures, and discharge cycle information. Further, the one or more parameters may include battery capacity, internal resistance, thermal conductivity, cell geometry, and cooling configuration. The one or more parameters and time series operational data may be captured in real time or retrieved from historical logs, which may be irregularly sampled with variable-length sequences, reflecting actual field usage conditions.

At step 704, the method 700 may include estimating a time series internal temperature profile of the battery using a neural network model based on the one or more parameters and the time series operational data. The TNM model may infer the time-resolved internal temperature trajectory using a physics-augmented neural operator, trained on data representing battery thermal behaviour.

At step 706, the method 700 may include generating a synchronized multi-feature time series dataset based on the time series operational data and the internal temperature profile. The preprocessor model may preprocess and integrates the original operational data with the estimated internal temperature profile to form a synchronized, multi-feature time-series dataset. The synchronized dataset serves as the structured input to the transformer-based SOH estimation model.

At step 708, the method 700 may include estimating SOH of the battery based on the generated synchronized multi-feature time series dataset using a transformer-based model. The TIDSIT model may estimate the SOH of the battery 112. The TIDSIT model may generate and fuse continuous-time embeddings to preserve irregular time intervals, Inverted embeddings to model inter-feature relationships, Temporal attention to identify key degradation patterns over time, and historical SOH trends to contextualize current health. Further, the TIDSIT model may output a scalar SOH value, representing the battery's 112 current usable capacity relative to its nominal value.

At step 710, the method 700 may include generating usage recommendations and maintenance actions based on the estimated SOH. In an embodiment, based on the estimated SOH value, If the SOH is high, the TIDSIT model may recommend normal operation or minor efficiency improvements. If the SOH is moderate or low, the TIDSIT model may generates usage recommendations, such as limiting discharge rates, reducing charge voltages, and adjusting thermal profiles. Further, if the SOH is critically low, the TIDSIT model may trigger automated maintenance alerts, such as battery replacement suggestions, service scheduling notices, and disabling high-load functions in safety critical systems.

In an exemplary embodiment, the disclosed method 700 may be deployed within an electric vehicle (EV) battery management system to monitor and estimate the State of Health (SOH) of a 10-cell lithium-ion battery pack. The battery has a nominal capacity of 60 Ah, and each cell is configured with an internal resistance of 0.005 Ω, thermal conductivity of 1.2 W/m·K, and a heat capacity of 850 J/kg·K. The system operates under realistic driving conditions over a single discharge cycle. During the discharge event, the system may receive irregularly sampled time-series measurements such as voltage readings ranging from 42.1V to 35.8V recorded at non-uniform intervals over a period of 38 minutes and current values fluctuating between 5.2A and 42.5A, reflecting varying acceleration and regenerative braking loads, and an ambient temperature of 29° C., while no internal temperature sensors are available.

At the beginning of the discharge cycle, the Thermal Neural Module (TNM) retrieves battery design parameters from the local database and receives the above voltage and current measurements in real-time. The TNM uses this data to simulate internal thermal behaviour, estimating that the core temperature rises from 30° C. to 54.7° over the discharge cycle, with brief peaks at 58° C. during high-current draws. The system then synchronizes the internal temperature estimates with the original voltage and current measurements to form a multi-feature time series dataset. Due to varying lengths of different discharge cycles in the training set, the current sequence of 114 time steps is padded to a standard length of 120, with appropriate masking to ensure only valid data points are considered during model inference. Further, the Time-Informed Dynamic Sequence Inverted Transformer (TIDSIT) model receives the synchronized dataset and applies continuous-time positional embeddings to capture the non-uniform spacing between samples, inverted data embeddings to process cross-variable dependencies among voltage, current, and temperature, and temporal attention to identify subtle patterns indicative of battery degradation.

In some embodiments, the TIDSIT model may receive the historical SOH estimates from the previous 10 discharge cycles such as [0.97, 0.96, 0.965, 0.95, 0.955, 0.94, 0.938, 0.925, 0.91, 0.80], indicating a gradual health decline. After processing, the TIDSIT model outputs an estimated SOH of 0.86 (or 86% of nominal capacity) for the current cycle, indicating moderate degradation. Based on the result, the TIDSIT module analyses the trend and automatically flags a recommendation to limit regenerative charging above 30A, which is linked to thermal stress peaks. Further, the TIDSIT model may schedule a diagnostic cycle during the next maintenance window.

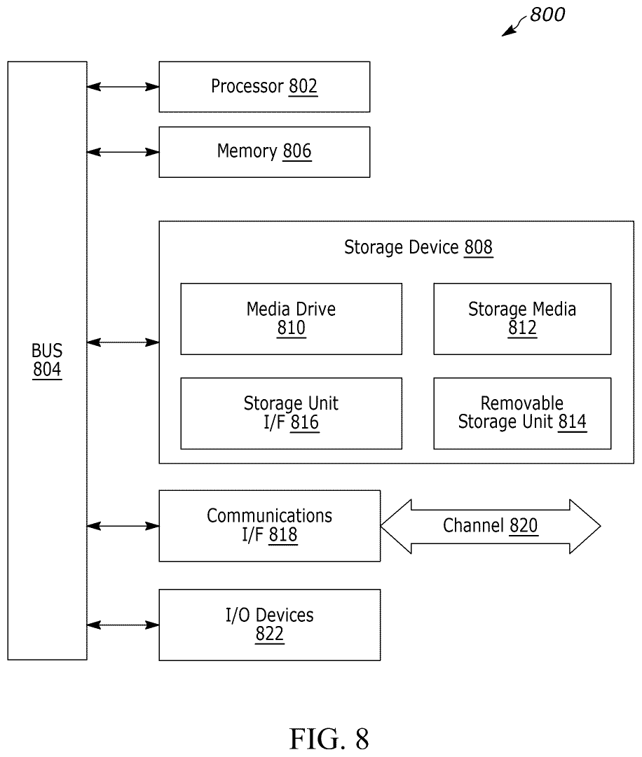

The disclosed methods and systems may be implemented on a conventional or a general-purpose computer system, such as a personal computer (PC) or server computer. Referring now to FIG. 8, an exemplary computing system 800 that may be employed to implement processing functionality for various embodiments (e.g., as a SIMD device, client device, server device, one or more processors, or the like) is illustrated. Those skilled in the relevant art will also recognize how to implement the invention using other computer systems or architectures. The computing system 800 may represent, for example, a user device such as a desktop, a laptop, a mobile phone, personal entertainment device, DVR, and so on, or any other type of special or general-purpose computing device as may be desirable or appropriate for a given application or environment. The computing system 800 may include one or more processors, such as a processor 802 that may be implemented using a general or special purpose processing engine such as, for example, a microprocessor, microcontroller, or other control logic. In this example, the processor 802 is connected to a bus 804 or other communication medium. In some embodiments, the processor 802 may be an Artificial Intelligence (AI) processor, which may be implemented as a Tensor Processing Unit (TPU), or a graphical processor unit, or a custom programmable solution Field-Programmable Gate Array (FPGA).

The computing system 800 may also include a memory 806 (main memory), for example, Random Access Memory (RAM) or other dynamic memory, for storing information and instructions to be executed by the processor 802. The memory 806 also may be used for storing temporary variables or other intermediate information during execution of instructions to be executed by the processor 802. The computing system 800 may likewise include a read only memory (“ROM”) or other static storage device coupled to bus 804 for storing static information and instructions for the processor 802.

The computing system 800 may also include a storage devices 808, which may include, for example, a media drive 810 and a removable storage interface. The media drive 810 may include a drive or other mechanism to support fixed or removable storage media, such as a hard disk drive, a floppy disk drive, a magnetic tape drive, an SD card port, a USB port, a micro-USB, an optical disk drive, a CD or DVD drive (R or RW), or other removable or fixed media drive. A storage media 812 may include, for example, a hard disk, magnetic tape, flash drive, or other fixed or removable medium that is read by and written to by the media drive 810. As these examples illustrate, the storage media 812 may include a computer-readable storage medium having stored there in particular computer software or data.

In alternative embodiments, the storage devices 808 may include other similar instrumentalities for allowing computer programs or other instructions or data to be loaded into the computing system 800. Such instrumentalities may include, for example, a removable storage unit 814 and a storage unit interface 816, such as a program cartridge and cartridge interface, a removable memory (for example, a flash memory or other removable memory module) and memory slot, and other removable storage units and interfaces that allow software and data to be transferred from the removable storage unit 814 to the computing system 800.

The computing system 800 may also include a communications interface 818. The communications interface 818 may be used to allow software and data to be transferred between the computing system 800 and external devices. Examples of the communications interface 818 may include a network interface (such as an Ethernet or other NIC card), a communications port (for example, a USB port, a micro-USB port), Near field Communication (NFC), etc. Software and data transferred via the communications interface 818 are in the form of signals which may be electronic, electromagnetic, optical, or other signals capable of being received by the communications interface 818. These signals are provided to the communications interface 818 via a channel 820. The channel 820 may carry signals and may be implemented using a wireless medium, wire or cable, fiber optics, or another communications medium. Some examples of the channel 820 may include a phone line, a cellular phone link, an RF link, a Bluetooth link, a network interface, a local or wide area network, and other communications channels.

The computing system 800 may include Input/Output (I/O) devices 822. Examples may include, but are not limited to a display, keypad, microphone, audio speakers, vibrating motor, LED lights, etc. The I/O devices 822 may receive input from a user and also display an output of the computation performed by the processor 802. In this document, the terms “computer program product” and “computer-readable medium” may be used generally to refer to media such as, for example, the memory 806, the storage devices 808, the removable storage unit 814, or signal(s) on the channel 820. These and other forms of computer-readable media may be involved in providing one or more sequences of one or more instructions to the processor 802 for execution. Such instructions, generally referred to as “computer program code” (which may be grouped in the form of computer programs or other groupings), when executed, enable the computing system 500 to perform features or functions of embodiments of the present invention.

In an embodiment where the elements are implemented using software, the software may be stored in a computer-readable medium and loaded into the computing system 800 using, for example, the removable storage unit 814, the media drive 810 or the communications interface 818. The control logic (in this example, software instructions or computer program code), when executed by the processor 802, causes the processor 802 to perform the functions of the invention as described herein.

It will be appreciated that, for clarity purposes, the above description has described embodiments of the invention with reference to different functional units and processors. However, it will be apparent that any suitable distribution of functionality between different functional units, processors or domains may be used without detracting from the invention. For example, functionality illustrated to be performed by separate processors or controllers may be performed by the same processor or controller. Hence, references to specific functional units are only to be seen as references to suitable means for providing the described functionality, rather than indicative of a strict logical or physical structure or organization.

Although the present invention has been described in connection with some embodiments, it is not intended to be limited to the specific form set forth herein. Rather, the scope of the present invention is limited only by the claims. Additionally, although a feature may appear to be described in connection with particular embodiments, one skilled in the art would recognize that various features of the described embodiments may be combined in accordance with the invention.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., are non-transitory. Examples include random access memory (RAM), read-only memory (ROM), volatile memory, non-volatile memory, hard drives, CD ROMs, DVDs, flash drives, disks, and any other known physical storage media. It is intended that the disclosure and examples be considered as exemplary only.

As will be appreciated by those skilled in the art, the techniques described in the various embodiments discussed above are not routine, or conventional, or well understood in the art. The techniques discussed above provide for innovative solutions to address the challenges associated with generating the knowledge graph of the data repository. The disclosed techniques offer several advantages over the existing methods:

Accurate SOH Estimation: The present disclosure enables direct processing of irregularly sampled variable-length multivariate time-series data without interpolation, truncation, or handcrafted feature extraction.

Improved Modelling of Internal Battery Conditions: The present disclosure incorporates a Thermal Neural Module (TNM) to estimate internal battery temperatures crucial for understanding degradation patterns without requiring internal sensors.

Continuous-Time Positional Embedding: The present disclosure employs a continuous-time embedding mechanism to effectively encode non-uniform time intervals between observations, preserving the true temporal structure of battery usage data.

Inverted Embedding for Cross-Feature Attention: The present disclosure utilizes an inverted embedding mechanism that models correlations across sensor channels such as voltage, current, temperature, enhancing the model's ability to learn inter-variable dynamics.

Physics-Augmented Neural Twin Architecture: The present disclosure combines data-driven deep learning with physics-informed modelling (via TNM), improving the interpretability and generalizability of SOH predictions across different batteries and conditions.

Generalizable Across Battery Types and Usage Profiles: The present disclosure is capable of learning degradation trends from various battery chemistries, configurations, and operating conditions due to its end-to-end architecture and physics-augmented framework.

The disclosed techniques offer several applications including:

Electric Vehicles (EVs): The present disclosure enables predictive maintenance, range forecasting, and safe operation under dynamic driving conditions.

Energy Storage Systems (ESSs): The present disclosure enable continuous monitoring and prediction of battery performance in grid-scale or renewable energy storage setups, supporting efficient energy dispatch and lifecycle optimization.

Battery Management Systems (BMS): The present disclosure integration with advanced BMS architectures enhances health diagnostics, safety management, and thermal regulation in lithium-ion battery packs

Consumer Electronics: The present disclosure ensure accurate battery life prediction and health reporting over extended use in portable devices such as smartphones, laptops, and drones.

Second-Life Battery Applications: The present disclosure enable assessing residual health of used batteries for repurposing in less demanding applications, enabling effective reuse and sustainability in battery life cycles.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

It is to be understood that the above description is intended to be illustrative, and not restrictive. For example, the above-discussed embodiments may be used in combination with each other. Many other embodiments will be apparent to those of skill in the art upon reviewing the above description.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the embodiments.

While the present invention has been described with reference to particular embodiments, it should be understood that the embodiments are illustrative and that the scope of the invention is not limited to these embodiments. Many variations, modifications, additions, and improvements to the embodiments described above are possible. It is contemplated that these variations, modifications, additions, and improvements fall within the scope of the invention.

We claim:

1. A method (700) for estimating State of Health (SOH) of a battery (112), the method (700) comprising:
receiving one or more parameters and time series operational data related to the battery (112);
estimating a time series internal temperature profile of the battery (112) using a neural network model based on the one or more parameters and the time series operational data, wherein the neural network model is a physics-informed Thermal Neural Module (TNM);
generating a synchronized multi-feature time series dataset based on the time series operational data and the internal temperature profile;
estimating the SOH of the battery (112) based on the generated synchronized multi-feature time series dataset using a transformer-based model, wherein the transformer-based model is a Time-Informed Dynamic Sequence Inverted Transformer (TIDSIT); and
generating usage recommendations and maintenance actions based on the estimated SOH.

2. The method (700) of claim 1, wherein the time series operational data related to the battery (112) is irregularly sampled with variable sequence lengths.

3. The method (700) of claim 1, wherein the one or more parameters comprises physical parameters, thermal design parameters, and time series operational data comprise voltage, current, battery discharge cycles, and external temperature of the battery (112).

4. The method (700) of claim 1, wherein generating the synchronized multi-feature time series dataset comprises preprocessing the time series operational data to handle irregular sampling intervals and variable sequence lengths.

5. The method (700) of claim 1, further comprising:
applying continuous-time positional embeddings to represent irregular sampling intervals of the time series operational data as a continuous function of time.

6. The method (700) of claim 1, further comprising:
padding the time series operational data to handle variable length sequences; and
applying a temporal attention with masking mechanism to ignore the padded values of the time series operational data.

7. The method (700) of claim 1, further comprising:
applying inverting embeddings to time series operational data to capture inter-variable correlations across the entire variable sequence.

8. A system (100) for estimating State of Health (SOH) of a battery (112), the system (100) comprising:
a processor (104); and
a memory (106) communicatively coupled to the processor (104), wherein the memory (106) stores processor-executable instructions, which, on execution, cause the processor (104) to:
receive one or more parameters and time series operational data related to the battery (112);
estimate a time series internal temperature profile of the battery (112) using a neural network model based on the one or more parameters and the time series operational data, wherein the neural network model is a physics-informed Thermal Neural Module (TNM);
generate a synchronized multi-feature time series dataset based on the time series operational data and the internal temperature profile;
estimate the SOH of the battery (112) based on the generated synchronized multi-feature time series dataset using a transformer-based model, wherein the transformer-based model is a Time-Informed Dynamic Sequence Inverted Transformer (TIDSIT); and
generate usage recommendations and maintenance actions based on the estimated SOH.

9. The system (100) of claim 8, wherein the time series operational data related to the battery (112) is irregularly sampled with variable sequence lengths.

10. The system (100) of claim 8, wherein the one or more parameters comprises physical parameters, thermal design parameters, and time series operational data comprising voltage, current, battery discharge cycles, and external temperature of the battery (112).

11. The system (100) of claim 8, wherein to generate the synchronized multi-feature time series dataset, the processor-executable instructions cause the processor (104) to preprocess the time series operational data to handle irregular sampling intervals and variable sequence lengths.

12. The system (100) of claim 8, wherein the processor-executable instructions cause the processor (104) to apply continuous-time positional embeddings to represent irregular sampling intervals of the time series operational data as a continuous function of time.

13. The system (100) of claim 8, wherein the processor-executable instructions cause the processor (104) to:
pad the time series operational data to handle variable length sequences; and
apply a temporal attention with masking mechanism to ignore the padded values of the time series operational data.

14. The system (100) of claim 8, wherein the processor-executable instructions cause the processor (104) to apply inverting embeddings to time series operational data to capture inter-variable correlations across the entire variable sequence.

15. A non-transitory computer-readable storage medium comprising instructions configured to estimate State of Health (SOH) of a battery (112), when executed, cause one or more processors (104) to at least:
receive one or more parameters and time series operational data related to the battery (112);
estimate a time series internal temperature profile of the battery (112) using a neural network model based on the one or more parameters and the time series operational data, wherein the neural network model is a physics-informed Thermal Neural Module (TNM);
generate a synchronized multi-feature time series dataset based on the time series operational data and the internal temperature profile;
estimate the SOH of the battery (112) based on the generated synchronized multi-feature time series dataset using a transformer-based model, wherein the transformer-based model is a Time-Informed Dynamic Sequence Inverted Transformer (TIDSIT); and
generate usage recommendations and maintenance actions based on the estimated SOH.

16. The non-transitory computer-readable storage medium of claim 15, wherein the time series operational data related to the battery (112) is irregularly sampled with variable sequence lengths.

17. The non-transitory computer-readable storage medium of claim 15, wherein the one or more parameters comprises physical parameters, thermal design parameters, and time series operational data comprising voltage, current, battery discharge cycles, and external temperature of the battery (112).

18. The non-transitory computer-readable storage medium of claim 15, wherein to generate the synchronized multi-feature time series dataset, the non-transitory computer-readable storage medium cause the one or more processor (104) to preprocess the time series operational data to handle irregular sampling intervals and variable sequence lengths.

19. The non-transitory computer-readable storage medium of claim 15, wherein the non-transitory computer-readable storage medium cause the one or more processor (104) to apply continuous-time positional embeddings to represent irregular sampling intervals of the time series operational data as a continuous function of time.

20. The non-transitory computer-readable storage medium of claim 15, wherein the non-transitory computer-readable storage medium cause the one or more processor (104) to:
pad the time series operational data to handle variable length sequences;
apply a temporal attention with masking mechanism to ignore the padded values of the time series operational data; and
apply inverting embeddings to time series operational data to capture inter-variable correlations across the entire variable sequence.
